(19) United States
(12) Patent Application Publication
(10) Pub. No.: US 2005/0123152 A1
(43) Pub. Date: Jun. 9, 2005

(54) Signal processors and associated methods

(76) Inventor: Anthony J. Magrath, Edinburgh (GB)

Correspondence Address: DICKSTEIN SHAPIRO MORIN & OSHINSKY LLP, 2101 L Street, NW, Washington, DC, 20037, US

(21) Appl. No.: 10/828,342

(22) Filed: Apr. 21, 2004

(30) Foreign Application Priority Data
Dec. 9, 2003 (GB) 0328505.3

(51) Int. Cl. H03G 3/00; H03G 9/00

(52) U.S. Cl. 381/104; 381/102

(57) ABSTRACT

A gain selector for use in a signal processor, particularly a peak limiter, comprising an audio input to receive a signal indicative of an audio signal, and a system gain processor to determine a system gain to be applied to the audio signal, such that the system gain is determined using a predetermined volume gain as well as the signal indicative of the audio signal.

This invention generally relates to audio signal processing. More particularly it relates to apparatus and methods for controlling the volume and signal level of an audio signal.

Conventional audio equipment, such as CD players, tape players, radio tuners, headphones, power amplifiers, microphones and loudspeakers and the like, have audio processing systems which use equalisation and gain/volume controls in their recording and playback chains to adjust the dynamic range of the audio signal to be output. Volume controls provide audio signals with a gain, typically up to 24 dB, in order to maintain an acceptable signal level.

Various signal-processing devices have been proposed to address other dynamic control issues, such as the compressor, which reduces the dynamic range of the input audio signal by increasing all amplitudes that are below a specified threshold. A compressor is generally implemented by applying an automatic gain control to the raw signal, where the gain is based on a mean-square measurement of the input signal and a specified threshold and compression ratio.

Another related signal-processing device is the expander, which also applies an automatic gain control to the raw signal, but here the gain is based on an expansion ratio as well as the mean-square measurement and a specified threshold. Expanders increase the dynamic range of an input audio signal by reducing the amplitude of all signals that are below a specified threshold, thereby “expanding” the dynamic range between the low and high amplitude components.

Peak limiters are another form of signal processing device, which modify the dynamic range of the input audio signal, ensuring that the output signal level does not exceed a particular threshold. Peak limiters are particularly useful in preventing, or at least minimising, the audible distortion due to clipping of the signal, in avoiding equipment overload, such as amplifier overstress, and in limiting headphone volume for safety reasons. Also recently digital Class D power amplifiers are being developed, which employ delta-sigma modulator techniques: if the input signal exceeds a threshold these can become unstable and produce gross audio effects. Peak limiters can be implemented in all such devices by applying a reduced gain to a raw audio signal, when a peak measurement of the raw audio signal exceeds a particular threshold. This serves to reduce the peak of the audio signal.

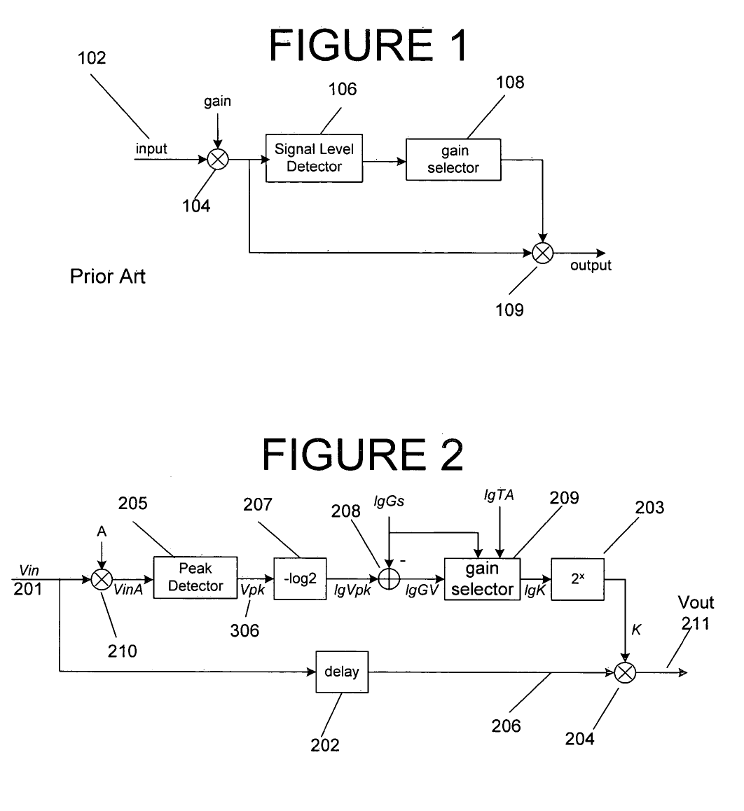

Compressors, expanders and peak limiters are often used together in a single audio processing system. They are also typically used in conjunction with a volume control gain. FIG. 1 shows a conventional circuit stage that can implement volume control together with one of compression, expansion or limiting. This circuit may be implemented in either the analogue or the digital domain, or in a combination of the two. An input audio signal on line 102 is provided to a gain block 104 where it is amplified according to a received volume control signal before being passed to a signal level detector 106. This signal level detector 106 senses the signal level, possibly with associated attack and decay times. The signal level detected is then passed to a gain selector 108, which uses the signal level to calculate the gain required to implement pre-programmed compression or expansion or limiter boundaries. The calculated gain is output from the gain selector 108 and provided to a multiplier 109, where it is multiplied with the amplified input signal, as output from the gain block 104. Therefore the volume control is provided by the gain block 104 and the compression, expansion or limiting control by the combination of the detector 106, gain selector 108 and the multiplier 109.

An exemplary digital system that combines all components in a single audio processing system is described in G. W. McNally, “Dynamic Range Control of Digital Audio Signals”, J. Audio Eng. Soc., Vol. 32, No. 5, May 1984. The system discloses cascaded separate compressor, expander and limiter stages. The limiter stage uses a level detector to determine the average or peak amplitude of an input signal, linear-to-logarithmic conversion and compression curve tables to determine a gain to apply, and a multiplier to apply this gain. The system seeks to achieve high linearity and low distortion, and employs a low pass filter to minimize perceptible distortion due to sudden gain steps.

In some applications, such as in digital power amplifiers, expansion and compression are not required functions, and it is sufficient if the signal processing circuitry only performs the limiting function and implements a volume control gain. In these applications, simple and cheap implementations are typically desirable, whilst still maintaining acceptable standards of dynamic adjustment.

In this regard, in an arrangement as shown in FIG. 1, the circuitry is quite complex, as the digital word length accommodated by this circuitry needs to be large enough to meet a reasonable increase in dynamic range provided by the volume control. Therefore, the hardware costs in this standard arrangement can be significant, resulting either from extra chip area in integrated realisations, or actual extra hardware components in a discrete implementation.

Furthermore, two multipliers are required, one to implement the volume control, and the other to implement the gain change required by the limiter. This is undesirable since multipliers are expensive to implement in hardware.

According to one aspect, the present invention provides a gain selector stage for selecting a gain for a signal processing circuit for amplifying digital audio signals, the gain selector comprising: an input for receiving a parameter of said signal; adjuster for adjusting said parameter dependent on a received volume control signal; and selector for selecting a gain dependent on said adjusted parameter.

The received volume control signal may be received in various forms, such as from a user as a linear indication of the volume level, or as a dB signal or as a log2 signal. Therefore processing of the volume control signal, such as by conversion or scaling, may be required before it is passed to the adjuster.

It is also to be appreciated that reference to “amplifying” a signal does not necessarily require an increase in the signal level, but that it is intended to cover all variations in the signal level, including attenuations.

Preferably the parameter is dependent on the peak signal level, for example being a signal level detected with defined attack and decay times. Other parameters such as the average signal level could alternatively be employed. Preferably the adjuster multiplies this by the volume control signal, which is determined by user control. This arrangement reduces the word length requirement of the parameter determining processor as the user volume control is applied after this in the control signal path.

Preferably the adjuster comprises a log converter coupled to the output of the parameter determining processor and an adder for adding this log output to the volume control signal, which is itself in the log domain (either received in that form or converted to the log domain). This replaces a multiplier with an adder, which is easier and cheaper to implement. It requires an inverse log circuit, to convert from the resulting log domain measure of gain to obtain a linear measure of gain to apply to multiplier 109, but this requires relatively little hardware or calculation, especially if using look-up tables for example.

The gain selector stage may also comprise an input to receive a threshold signal; a comparator for comparing the output of the adjuster with the threshold signal; and wherein the selector selects the gain dependent on the comparison. It therefore follows that the selector selects the gain dependent on both the received volume control signal and the input audio signal.

It is to be appreciated that the gain selector stage may be comprised of just the gain selector (209), as shown in FIG. 2, or it may also comprise at least one of the log2 converter (207) and the adder (208) and the inverse log stage 203.

According to a further aspect, the present invention provides a peak detector comprising an input for receiving a signal, processor for determining peak levels in the signal and output for outputting a signal dependent on said peak levels and a time dependent decay characteristic, wherein the decay characteristic is further dependent on the frequency of said received signal.

According to another aspect, the present invention provides a gain selector for use in a signal level controller, such as a peak limiter, the gain selector comprising:
an audio input to receive a signal indicative of an audio signal;
an input to receive a signal indicative of a volume gain; and
processor to determine a system gain to be applied to the audio signal, such that the system gain is determined using the indicative volume gain signal as well as the indicative audio signal.

In this regard the signal level controller is a device that controls the signal level. It may be a component of an amplifier, such as a peak detector, an expander or a compressor.

The “indicative” input signal term is intended to illustrate that the signal being utilised need not be the input signal itself, but an equivalent or related signal, such as one that has undergone additional processing or been converted to the log domain. The same applies to the other signals termed “indicative”. Most preferably the indicative signals are in the log 2 domain.

Preferably the gain selector further comprises an input to receive a signal indicative of a threshold; and a comparator for comparing the gained indicative signal with the signal indicative of the threshold, wherein the system gain processor determines the system gain using the comparison. It is also preferably that the indicative threshold signal represents the threshold in the log domain, the indicative volume control signal represents a volume gain in the log domain and the signal indicative of the audio signal is in the log domain. Therefore, in this regard, the gain selector further comprises an adder to apply the indicative volume control signal to the indicative audio signal to obtain a gained indicative signal for use in determining the system gain.

According to another aspect, the present invention provides a method of determining a signal gain to be applied to an audio signal comprising:
receiving a signal indicative of the audio signal;
receiving a signal indicative of a volume gain; and
combining the indicative audio signal and the indicative volume gain signal using an adder; and
determining a system gain to be applied to the audio signal using the combined signal.

Preferably the method further comprises receiving a signal indicative of a threshold; and comparing the gained indicative signal with the signal indicative of the threshold, wherein a system gain processor determines the system gain using the comparison. It is also again preferable that the indicative threshold signal represents the threshold in the log domain, the indicative volume control signal represents a volume gain in the log domain and the signal indicative of the audio signal is in the log domain. Therefore, in this regard, the method further comprise adding the indicative volume control signal to the indicative audio signal to obtain a gained indicative signal for use in determining the system gain.

Preferably the method further comprises determining the system gain by a variable gain function, such as when the gained indicative signal is less than the indicative threshold signal and a positive signal polarity is utilised, in order to implement peak limiter functionality. Alternatively, a variable gain function may be utilised when the gained indicative signal is greater than the indicative threshold signal and an inverted signal polarity is utilised. In general, a variable gain function is one where the gain is defined by signals other than, or together with, the volume control gain.

Where a positive signal polarity is utilised, the variable gain function is preferably:
K=2^{lgK} where
   lgK=lgGs+m(lgGV+lgTA)
   where K is the system gain, lgGs is the indicative volume control signal, lgGV is the gained indicative signal, lgTA is the indicative threshold signal and m is a value indicative of a predetermined operation curve characteristic of the gain selector.

When a negative signal polarity is utilised, a negative version of these equations could be utilised. Obviously, similar equations and functionality may be obtained with alternative sign conventions for the indicative signals in these equations, e.g. each signal may be multiplied by a factor of-i when derived and then subtracted rather than added.

In the implementation of a compressor, an appropriate alternative variable gain function may be used when the gained indicative signal is greater than the indicative threshold signal (and a positive sign convention utilised). Further, where other dynamic controls are to be implemented, such as a combined compressor and peak limiter, different thresholds may be utilised as well as different gain functions each side of the threshold.

According to another aspect, the present invention provides a digital signal processor, such as a gain selector comprising:
an input to receive a signal indicative of a volume gain;
an input to receive a signal indicative of an audio signal; and
an adder to apply the indicative volume gain signal to the indicative audio signal to obtain a gained output signal for use in the selection of the system gain.

Standard gain selectors, such as 108 used in the system of FIG. 1, receive only the signal indicative of an audio signal, and require a separate preceding volume control, so the system has to perform separate calculations for volume control and gain selection. In the present aspect of the invention, the limiting control and a volume control are implemented by merging the volume functionality with the limiter functionality. This advantageously simplifies the circuitry.

To illustrate this simplification, consider the case of a standard volume control being packaged with a standard peak limiter, such as shown in FIG. 1. In that known configuration, one gain block is used to provide the gain of the volume control (104), and another is contained within the dynamic range limiter (109). Therefore, two gain blocks are used in that arrangement. By determining the system gain using an indicative audio input signal as well as a volume control signal, it is possible to merge the limiting and volume control functionality, which in turn advantageously reduces the number of gain blocks, and hence multipliers that are required. That is, the arrangement now only requires the audio signal to be multiplied by one multiplier rather than two.

Further, by providing the volume control function via the incorporation of a simple adder in the log domain part of the control path, advantageously the need for audio signal multiplication in the control path is avoided.

In a further aspect, the present invention provides a signal level detector comprising an input to receive an input audio signal;
comparator for comparing the input audio signal with an output signal to obtain a compared signal; and
processor operable in a decay mode when the input audio signal is smaller than the output signal, whereby in the decay mode, the processor is configured to decrease the amplitude of the compared signal; and logic device for controlling the operation of the processor in the decay mode based upon a trigger related to the frequency of the input audio signal.

The processor is preferably a multiplexer.

In a still further aspect, the present invention provides a method of determining a signal level of an audio signal comprising:
receiving an input audio signal;
comparing the input audio signal with a previous output signal to obtain a difference signal;
generating a scaling signal by scaling the difference signal using an attack parameter or a decay parameter, depending upon the comparison;
combining the scaling signal with the previous output signal to obtain a signal, indicative of the signal level of the input audio signal, characterised in that the method comprises:
controlling the generation of the scaling signal when scaled by the decay parameter, using a trigger related to the frequency of the input audio signal.

Preferably the trigger is generated when a change of sign of the input signal occurs or a timeout occurs.

By controlling the operation of the signal level detector, such as a peak detector, and making the decay rate proportional to the frequency of the input signal, signal distortion can be minimized.

The present invention will now be described with reference to the accompanying drawings, in which:

FIG. 1 illustrates a known circuit stage that can implement a volume control gain together with a compression, expansion or limiting function.

FIG. 2 schematically illustrates a signal processor according one embodiment of the present invention.

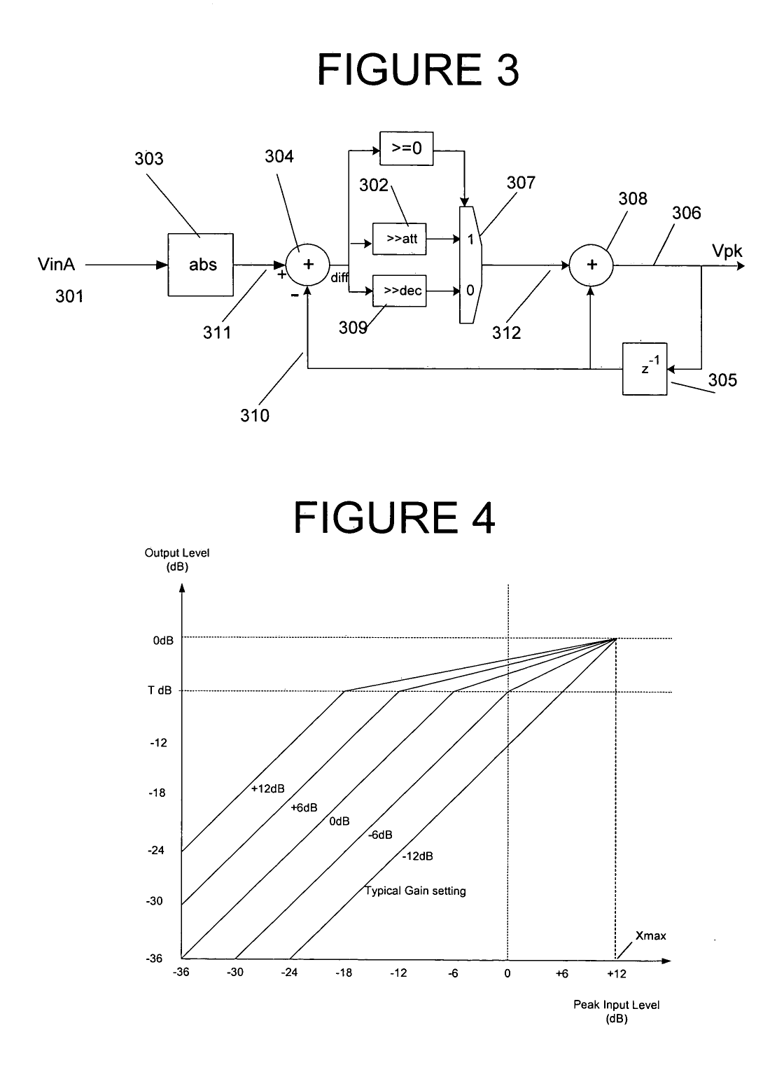

FIG. 3 schematically illustrates a peak detector according to an embodiment of the present invention, which can be utilised in the arrangement of FIG. 2.

FIG. 4 schematically illustrates a set of characteristic curves implemented by a gain selector according to an embodiment of the invention.

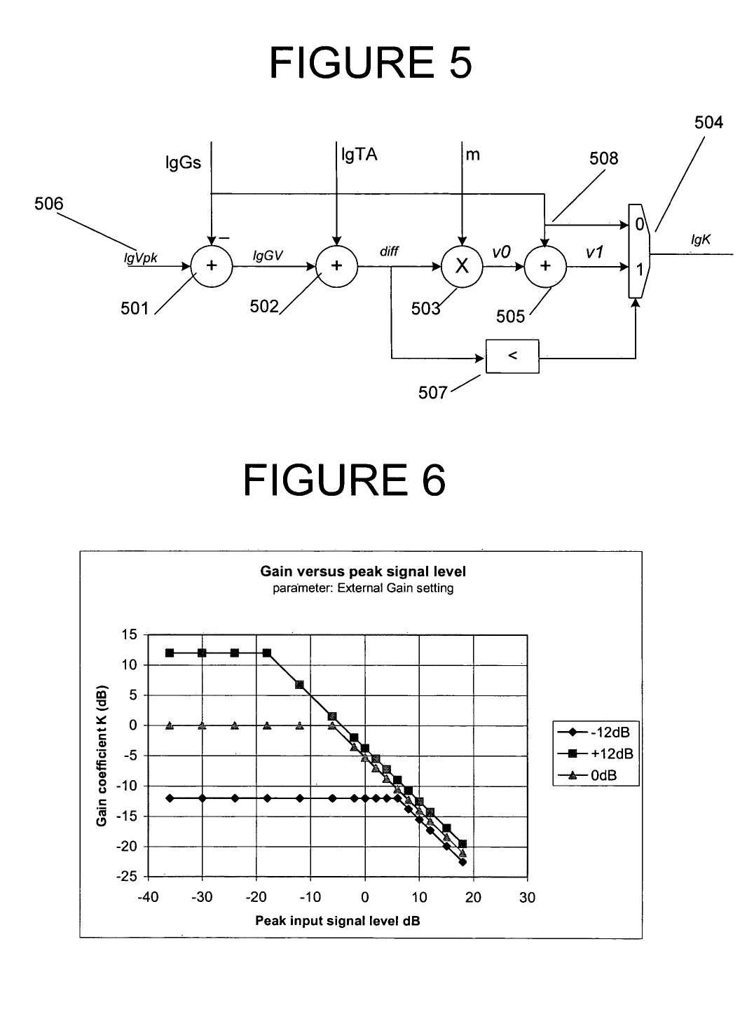

FIG. 5 schematically illustrates a gain selector according to an embodiment of the present invention.

FIG. 6 illustrates a graph of the gain coefficient K against the peak input signal level as implemented by a gain selector according to an embodiment of the present invention.

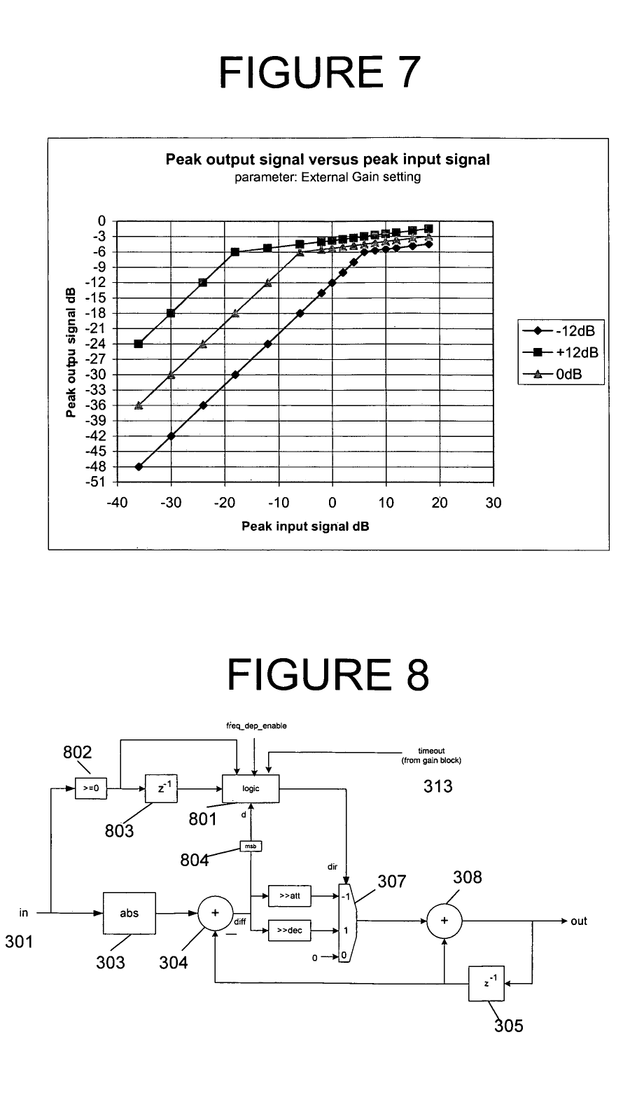

FIG. 7 illustrates a graph of the peak output signal against the peak input signal for a number of different static gain or volume control signal values as implemented by a signal processor according to an embodiment of the present invention.

FIG. 8 illustrates a gain selector according to a further embodiment of the present invention.

With reference to FIG. 2, a first embodiment of a signal processor according to the present invention is illustrated. This signal processor may be used in any audio processing device, such as a digital amplifier controller or a digital to analogue converter.

The circuit shown in FIG. 2 has a feed-forward design. The input signal 201 is passed to two different paths, the upper one being the control path and the lower one being the gain path. Since this limiter is of feed-forward design, the gain path includes a delay 202. This delay 202 is included to prevent sudden peaks from passing through the multiplier 204 to the system output before the gain control signal can propagate through the parallel control path, in order to account for latency implicit in the calculation circuitry. However, a cost-driven system design may well dispense with this delay element, since the distortion audible from a single isolated peak is not severe, and the hardware required for a long enough delay element is substantial.

On the control path, the input signal Vin, 201 is passed to an attenuator 210, which multiplies the input signal 201 by a scale factor A to attenuate it. A suitable scale factor would be ⅛, i.e. approximately −18 dB. This value of −18 dB allows for 18 dB headroom on the incoming signal, and is intended to ensure that the maximum signal level to the preceding peak detector 205 and log2 block 207 is 0 dB. Having the maximum signal level as 0 dB means that the results of the subsequent log2 calculations are always negative, which simplifies the implementation. 0 dB should be interpreted as a digital signal whose value lies between +1.000 and −1.000.

It is to be appreciated that values other than −18 dB may be chosen for the scale factor. Preferably the scale factor is of the order of ½^{N}, as this corresponds to a simple bit-shift of the binary representation of the signal, with very little implementation cost. The attenuator may be omitted altogether (A=1) at the expense of more complex downstream circuitry.

The attenuated input signal VinA=Vin*A is then passed to the peak detector 205. The peak detector 205 determines the peak signal level Vpk by tracking the envelope of the signal input thereto, using predefined attack and decay times. These attack and decay time parameters are generally chosen in order to obtain appropriate distortion and noise-masking qualities.

The peak detector 205 operates by finding the difference between its previous output and the absolute value of the input. The difference signal is then scaled by the attack or decay rate coefficient and the scaled signal is then added to the previous output. In this way, the output is ramped exponentially towards the input signal and thereby tracks it. The peak detector 205 is preferably configured with fast attack (rise time) and slow decay rates, so that the output Vpk tracks the absolute value of the peak of the input signal. This allows sudden peaks to be responded to while minimising distortion due to gain modulation after this event.

An example of a single channel digital peak detector, which can be used in the signal processor of FIG. 2, is shown in FIG. 3. The input signal VinA (301) is firstly passed to device 303, and an absolute value 311 of the signal output therefrom. The absolute value 311 is then passed to adder 304, where the absolute value 311 is compared with the peak value of the previous output 310. The comparison is performed by subtracting the previous output value 310 from the absolute input value 311. This is made possible using delay 305, via which the previous output value is passed to the adder 304 for the comparison.

If the absolute input value 311 is greater than the previous output value 310 then the difference signal will be multiplied or scaled by the attack rate coefficient at 302, before being passed through a multiplexer 307.

The multiplied difference signal 312 output from multiplexer 307 is then added, at adder 308, to the previous output value 306 that was stored by the delay 305. This difference signal 312 will be positive, so will tend to increase the signal at 306. In other words, the attack rate is used when the input signal is greater than the output of the peak detector, in order to increase the output signal of the peak detector. The response at 306 to a step increase in the envelope of the input signal at 301 will be to ramp up exponentially to a new asymptotic level at 306, this level representing the new peak value of the input signal 301.

Should the absolute value 311 of the input signal fall below the previous output value 310, the difference signal will become negative. Then the difference signal output from 304 will be multiplied or scaled by the decay rate coefficient at 309 and this scaled value passed through the multiplexer 307. The multiplied difference signal output 312 from multiplexer 307, which will be negative will then be added at adder 308 to the last output value 306 that was stored by the delay 305. Therefore, the decay rate is used when the input signal is smaller than the output signal of the peak detector, so that a decrease of the output signal of the peak detector is desired.

Note that if say a sine wave is applied to 301, then for most of the cycle, the signal 311 will be smaller than the peak detected signal at 310. This will cause some droop on the output at 306, as determined by the decay rate coefficient of 309, until the next peak of the input signal occurs, at which time the output at 306 will increase with an attack rate determined by the attack rate coefficient in 302. Typically the attack rate is set significantly faster than the decay rate, so the amount of droop within the input cycle is small compared to the detected peak value

Preferably the attack and decay multiplication coefficients are powers of two, so that these multiplications become mere bit-shifts, with much smaller hardware requirements.

Returning to FIG. 2, the signal Vpk 306 output from the peak detector 205 is then passed to the log2 block 207 to generate a signal lgVpk indicative of the audio signal input 201. This block implements the equation:
lgVpk=−log2(x) (1)
where x is the signal Vpk 306.

The minus sign is included to simplify later signal processing by making this signal positive polarity, but this is not essential. Note that large values of lgVpk correspond to small values of the input signal amplitude, and values near zero correspond to signal nearly at peak value. Therefore, lgVpk is a decreasing measure of the original audio signal peak amplitude.

It would be possible, at the expense of a little extra circuitry, for a person skilled in the art to modify the system described below omitting the above minus sign, so that lgVpk=+log2(Vpk). In this situation lgVpk would be of negative polarity and an increasing measure of the original audio signal peak amplitude. The remainder of this description, however, will assume lgVpk is a decreasing measure of the audio signal with positive signal polarity.

In this embodiment, to obtain a logarithm of the signal Vpk 306, a look up table is utilised together with a binary floating point representation of the input signal x (which equals Vpk). Preferably the exponent and mantissa of this representation are calculated separately to reduce the size of the lookup table. The relationship between the two representations is as follows:

$$\begin{matrix}log 2 ( x ) = log 2 ( m \cdot {2}^{- N} ) & ( 2 ) \\ = - N + log 2 ( m ) & ( 3 )\end{matrix}$$

where 0.5=<m<1, m is the mantissa and N is the exponent.

As an example of the calculations required, the input value x is left shifted until it has a value 0.5<=x<1. The exponent is the number of left shifts required. Also, where the result of the left shifts is a binary number 0.1XXXXXXX, the mantissa is the XXXXXXX component. It is this value that is looked up in the tables, and that looked up value is then combined with the exponent, as per equation (3).

It is to be appreciated that the final value is found by combining the exponent and mantissa bits, without requiring an addition. This is only possible for x input values less than 1. It is for this reason that the input to the peak detector is scaled down by the attenuator 210, to ensure that input values to the log calculator 207 will be less than 1. By ensuring the values of the mantissa will be less than 1, they can therefore readily be combined with the exponent, being an integer, without the need for an adder. This therefore greatly simplifies the circuitry required.

Referring again to FIG. 2, the output lgVpk from the log2 block 207 is passed to an adder 208, which generates a signal lgGV which is a decreasing measure of the amplitude that would result from applying volume control gain Gs (and scale factor A) to the input signal Vin 201, by subtracting an appropriate log volume control lgGs, where lgGs=+log2(Gs) and can be considered an indicative volume control signal. So, at adder 208, the following equation is calculated:
lgGV=lgVpk−lgGs (4)
to give the gained indicative signal lgGV.

As the calculations here are in the log2 domain, the indicative volume control signal lgGs utilised here also needs to be in the log2 domain. Where the series of received system gain values is not defined or stored in the log2 domain, it needs to be converted. If this value were in dB, a division by 6 would achieve this conversion, which can generally be effected with a look up table. This look-up table can be very simple if the series of possible system gain values are defined in terms of gain steps of (6.02/2^{N})dB.

The gain selector 209 determines an appropriate gain to be applied to the raw input signal Vin 201, based upon the log2 value input (i.e. lgGV) and predetermined input/output characteristics. For instance, FIG. 4 illustrates an example of a set of input-output characteristic curves from input Vin 201 to output Vout 211 that the gain selector 209 could be configured to implement.

The characteristic curves of FIG. 4 show the desired operation of a limiter for a number of different volume control gains, ranging from +12 dB for the top graph down to −12 dB for the bottom graph in 6 dB decrements. Essentially FIG. 4 shows that when the peak signal is below the Threshold level T, the signal will have the volume control Gs applied linearly. Once the Threshold T is reached, however, the gain of the limiter is reduced in order to prevent the output signal exceeding 0 dB and therefore to prevent or minimise clipping and other undesirable characteristics. Referring to FIG. 4, the degree of reduction between T dB and 0 dB for each different volume control gain differs. Therefore, where the volume control gain is +12 dB, a more gradual reduction of the output signal occurs, as compared with −12 dB, which has a shorter and sharper reduction once the Threshold T is reached.

That is, the slope m of the characteristic curve between Tdb and 0 dB, depends on the volume control gain Gs, in order for the curves to converge at (Xmax,0) as shown. Typically there might be say 256 possible gain steps in a system to ensure adequate smoothness of the gain control, so a large look-up table would be required to calculate m as a function of Gs, even for fixed Xmax (i.e. the maximum peak input level) and T.

In practice the alternative family of curves as shown in FIG. 7 gives an acceptable amount of controlled peak limiting before the onset of hard limiting, and avoids the cost and complexity of the case by case calculation of m as required by the characteristic curves of FIG. 4.

FIG. 7 illustrates a graph of the peak output signal at Vout 211 against the peak input signal at Vin 201 for a number of different volume control gain values Gs. The top curve represents a volume control gain of +12 dB, the middle graph a volume control gain of 0 dB and the lower graph a volume control gain of −12 dB. In all of these graphs, the output was linearly increased by the applicable volume control gain, until the Threshold was reached, at approximately −6 dB. After this Threshold the gain applied to the input signal is reduced as the output signal increase towards 0 dB.

Referring to FIG. 5, a gain selector is illustrated which is suitable for implementing the characteristic curves of FIG. 7. It is also suitable for use as the gain selector 209 in the circuit of FIG. 2. It is to be noted that the gain selector of FIG. 5 includes an adder 501 equivalent to adder 208 of FIG. 2 for the addition of the log volume control gain lgGs; in other words the adder is not considered separate in this description.

Therefore, in FIG. 5, the log2 value 506 input to the selector can be considered equivalent to the output lgVpk from the log2 block 207 of FIG. 2. In FIG. 5, the log volume control gain lgGs is subtracted from lgVpk by adder 501 in order to provide a gained indicative signal lgGV, a decreasing measure of the amplitude that would result from applying volume control gain Gs (and any appropriate scale factor A) to the input signal Vin 201 (or more strictly to the peak-detected signal represented in the log domain by lgVpk, but this distinction is minor if the droop within the peak detector is small).

To define the break point of the input-output curves of FIG. 7, lgGV is then compared with the threshold value lgTA at adder 502. The threshold value is indicative of the signal level at which signal limiting is initiated. However since calculations are in the log2 domain, the threshold signal level must also be converted into the log2 domain, being represented by log2(T). Also the previous gain scaling by A must be allowed for, so
lgTA=log2(T*A). (5)

For example, for T=½(i.e. −6 dB) and A=⅛(−18 dB), lgTA=log2(½*⅛)=−4.

At adder 502, the comparison between the anticipated gained input signal peak level and an appropriate Threshold value can be achieved by adding a negative threshold value lgTA (an increasing measure of the threshold) to the signal-related value of lgGV (a decreasing measure of the gained signal).

The summed signal output from adder 502 is designated as “diff” in FIG. 5. This diff signal is a decreasing measure of the amount by which the anticipated gained peak-detected signal exceeds the threshold. This “diff” signal is sent down two different paths, one path is input to multiplier 503, and the other path, to comparator 507, whose output drives the control input of multiplexer 504.

If the peaks of the input signal Vin, when gained by Gs are less than or equal to the threshold level T, then the input signal does not need limiting and can be increased by the volume control gain. Remembering that lgVpk and lgGV in this embodiment are decreasing measures of the audio input, lgGV+lgTA (i.e. diff) will be greater or equal than zero in this case. The sign of diff is determined by sign-detector 507 and used to control multiplexer 504. Therefore, when it is determined that the input signal does not need limiting, the log gain lgK output from multiplexer 504, and accordingly from the gain selector itself, is lgGs. The volume control gain value lgGs is input to the multiplexer 504 via path 508.

However, if the peaks of the input signal Vin, when gained by Gs are greater than the threshold level T, then diff will be less than zero so then the gain is reduced linearly according to the slope value m, where m is the slope of the appropriate characteristic curve above the threshold T. as per FIG. 7 (m=0.875 in this example). Therefore, in this situation, the log gain lgK output from multiplexer 504 will be:
lgK=lgGs+m(lgGV+lgTA) (6)
as implemented by multiplier 503 and adder 505. Note that if m=½^{M}, then multiplier 503 can become a mere bit-shift scaling of the signal: in general m can be defined at a low resolution to minimise the size and cost of the multiplier.

Therefore, in the gain selector of FIG. 5, the log gain lgK output will be the log volume control gain lgGs, unless it is estimated that the peaks of the gained input signal gs.Vin would have exceeded the Threshold T. (i.e. lgVpk−lgGs=lgGV is less than lgTA) at which point the log gain is linearly reduced.

FIG. 6 illustrates this, where the gain coefficient K is mapped against the peak input signal level, for a number of different volume control gain values. The top graph is for volume control gain value +12 dB, the middle graph is for volume control gain value 0 dB and the lower graph is for volume control gain value −12 dB. For each of these graphs, the gain coefficient is kept static at their respective values, until the Threshold value is reached. Once the threshold is reached, the gain value for each of the graphs is reduced linearly by an amount dependent upon slope m and volume control gain Gs.

The circuit schematic shown in FIG. 5 is just a general outline of the components that may be utilised to effect this embodiment of the invention. Preferably a gain ramp is included in order to smooth the effect of the added volume control gain Gs, which provides a stepwise ramp between the old gain setting and the new setting. Preferably the gain ramp is a 13-bit counter, and the total number of values for the full gain range is 2720. With a 5.5 kHz/6 kHz clock the entire range of the counter can be traversed in about 0.5 seconds. By updating the gain over a large number of steps, and with a small stepped gain increase each time, clicking should be inaudible.

It is to be appreciated that the value lgGV, which is compared to the Threshold, is an estimate, in a parallel control path, of the intended signal output. That is, it is made up of the volume control gain and the input signal. This is a wholly different approach than heretofore known limiters, which compare the Threshold only against the input signal, after it has already been affected by a preceding gain control in the signal path.

Merging the volume control and the limiter function has advantageously resulted in a reduction of hardware requirements, as a separate volume control is no longer required. Further, merging the volume control with the limiter functionality results in a reduction of the digital word length required. The Threshold gain values also need to be updated accordingly, so that they are defined as corresponding values in the log domain, but this would not result in an increase of circuitry. Therefore, by merging the volume control and limiter functions, an overall reduction in the circuitry requirements results, as well as the required digital headroom.

Referring again to FIG. 2, with the log gain lgK determined, it is output from the gain selector 209 and passed to an inverse log converter 203, which performs the equation y=2^{x}, i.e. it produces a gain K where K=2^{lgK}, which can then be directly passed to multiplier 204 to apply the appropriate system gain K to the original audio input signal Vin 201 as desired to provide the system audio output signal Vout 211.

To perform this conversion, which is essentially the reverse operation as performed by the log converter 207, the binary representation of the signal is taken and a bit inversion is performed to find its l's complement inversion. This inversion representation is then split at its radix point into integer and fractional bits.

The integer bits are converted into a 2's complement number, which is the exponent to be used as the right-shift. The fractional bits are looked up in a look up table, and the result is the mantissa, which is used as the multiply value in the conversion.

Table 1 below provides some examples using lower precision arithmetic and 2's complement inversion for clarity.

TABLE 1

| Calculation | x (binary) | ˜x | expo | Mantissa | lookup |
|---|---|---|---|---|---|
| 2^{-2.25} = 2^{<2} * 2^{-0.25} | 101.11 | 010.01 | 2 | 0.25 | 0.84 |
| 2^{2.25} = 2³ * 2^{-0.75} | 010.01 | 101.11 | −3 | 0.75 | 0.59 |
| 2⁻² = 2⁻² | 110.00 | 010.00 | 2 | 0 | 1 |
| 2³ = 2³ | 011.00 | 101.00 | −3 | 0 | 1 |

The conversion is performed in the inversion log block 203, and the mantissa and exponent values in the dB domain are passed to the gain block 204.

The gain block 204 serves to multiply the signal 206 received from the delay 202 by the gain received from the inversion log block 203. This is achieved by multiplying the signal 206 input to the gain block 204 by the mantissa and the shifting the resultant signal by the exponent. In this regard, the raw input signal Vin is multiplied by either the gain K, where this gain K is either Gs or the gain derivable from equation (6).

In a further preferred embodiment, in order to reduce audible distortion, it is desirable only to change the gain applied to the input signal 206 when the signal crosses zero; that is when it changes from a positive value to a negative value or vice versa. This is to prevent audible clicking when the gain changes. Therefore, the gain block 204 includes a zero-cross detector, which determines when the input signal 206 changes from a positive value to a negative value or vice versa.

In another embodiment of the invention, an additional feature is to make the decay rate of the peak detector frequency dependent. It has been found that by making the decay rate inversely proportional to the frequency of the input signal, signal distortion can be minimized. To implement this feature, it was recognised that the frequency of the input signal can be monitored via the periodicity of its sign changes. With reference to FIG. 8, this function is implemented by incorporating a logic block 801 in the peak detector 205. It will be appreciated that FIG. 8 is a modified version of the peak detector of FIG. 3. Like reference numerals will be used for like features.

In the peak detector of FIG. 8, the input signal 301, in addition to being passed to block 303, which determines the absolute value of the signal, is input to a comparator 802, which determines if the input signal is greater than or equal to zero. If the input signal is in 2's complement arithmetic, a most significant bit (msb) extraction block, which outputs the sign bit, can be used instead of a full comparator at 802. For instance, where an msb is used, it will output a “1” if the signal is less than zero or a “0” if the signal is equal or greater than zero.

The output from comparator 802 is then passed directly to the logic block 801 and also to delay 803. The delay 803 enables the logic block to compare the sign of the current input signal with that of the previous one to determine whether a change of sign has occurred.

The logic block also receives a timeout signal 313 from gain block 204 and a signal d from msb block 804, which informs the logic block of the sign of the diff signal from comparator 304. This comparator 304 again can be of any type, such as a full comparator or an msb extraction block.

The timeout signal 313 is generated by the zero cross detector (not shown) incorporated in the gain block 204. The time out signal 313 ensures that the gain will be updated even if the input signal 306 to the gain block has a large DC value, and is generated from a counter in the zero-cross detector. The timeout counter has a period corresponding to the lowest frequency of the input signal. For example, the timeout counter should have a period of about 50 ms where the lowest input frequency is 20 Hz.

Logic block 801 contains simple combinatorial logic responding to its various inputs to output a signal to control the multiplexer 307.

Similarly to the circuit of FIG. 3, if diff is positive, i.e. d=0, then the difference signal diff will be multiplied by the attack rate coefficient at 302, before being passed through the multiplexer 307, and then being integrated every clock cycle by adder 308 and delay 305 to cause the output Vpk to ramp up to an appropriate asymptote.

However, if diff is negative, i.e. d=1, the multiplexer 307 will usually only output a zero, so the integrated output Vpk 306 will remain unchanged. A negative signal diff will only be multiplied by the decay rate coefficient at 309, before being passed through the multiplexer 307, if either a zero cross is detected as above, or if the timeout signal 313 is received from gain block 204. Therefore, during a decay phase, the logic block 801 serves to hold the multiplexer 307 unchanged until the sign of the input signal changes, or the time out signal 313 is received from gain block 204. In this way the rate of the decay function is only implemented at zero-crossings of the input signal, and so is dependent upon the frequency of the input signal, which aids in minimizing signal distortion. This approach can also be utilised in the attack phase, although it is preferable not to, as this could restrict the limiter's response time in preventing clipping.

During the decay phase, distortion will occur if the output changes quickly with respect to the period of the input signal. This is because the waveform will be distorted by the gain change. With the above technique, the gain can only change after each half-cycle of the input signal, therefore waveform distortion is minimised.

The logic block 801 also includes an input to enable and disable the frequency dependent function as appropriate. When the frequency dependent function is disabled, operation reverts to that described with respect to FIG. 3.

It is to be appreciated that whilst this embodiment of the invention has only been described in relation to controlling the operation in the decay, no doubt many effective alternatives will occur to the skilled person and it will be understood that the invention is not limited to the described embodiments and encompasses modifications apparent to those skilled in the art lying within the scope of the claims appended hereto.

For example, although the embodiment describes detecting a signal peak, alternative signal level characteristics may be determined, such as RMS or average signal values, or a combination thereof.

Also, embodiments of the present invention need not be restricted to implementation in a peak limiter, but may equally be applied to an expander or a compressor. In this regard, the implementation would still be of the general form shown in FIG. 2, but the implementation of the gain selector 209 would be different that that described herein, in that it would be adapted to suit the functionality or gain law of an expander or compressor, as appropriate.

Further, the embodiments of the present invention have been described in relation to a single channel system. Single channel systems are most applicable for software implementations. Where a hardware implementation is desired, a two channel system would be used, and the left and right channels interleaved through the hardware. A peak detection calculation would be undertaken for each channel, and preferably the maximum value of the two peak detection calculations is used for both channels. Therefore, embodiments of the present invention may be implemented in hardware or an equivalent software algorithm, which is preferably economical in code and computational requirement.

The embodiments of the invention have been described with the aid of functional building blocks and method steps illustrating the performance of specified functions and relationships thereof. The boundaries of these functional building blocks and method steps have been arbitrarily defined herein for the convenience of the description. Alternate boundaries can be defined so long as the specified functions and relationships thereof are appropriately performed. Any such alternate boundaries are thus within the scope of the claimed invention. One skilled in the art will recognise that these functional building blocks can be implemented by discrete components, application specific integrated circuits, processors executing appropriate software and the like or any combination thereof.

Unless the context clearly requires otherwise, throughout the description and the claims, the words “comprise”, “comprising”, and the like, are to be construed in an inclusive as opposed to an exclusive or exhaustive sense; that is to say, in the sense of “including, but not limited to”.

Any discussion of the known arrangements throughout the specification is not an admission that this is widely known or forms part of the common general knowledge in the field.

Embodiments of the invention also consists in any individual features described or implicit herein or shown or implicit in the drawings or any combination of any such features or any generalisation of any such features or combination, which extends to equivalents thereof. Thus, the breadth and scope of the present invention should not be limited by any of the above-described exemplary embodiments. Each feature disclosed in the specification, including the claims, abstract and drawings may be replaced by alternative features serving the same, equivalent or similar purposes, unless expressly stated otherwise.

1. A gain selector stage for selecting a gain for a signal processing circuit for amplifying digital audio signals, the stage comprising: an input for receiving a parameter of said signal; adjuster for adjusting said parameter dependent on a received volume control signal; and selector for selecting a gain dependent on said adjusted parameter.

2. A selector stage according to claim 1 wherein the received volume control signal is input to a processor before being passed to the adjuster.

3. A selector stage according to claim 2 wherein the processor comprises a log converter and/or a scaling means.

4. A selector stage according to claim 1 wherein the adjuster comprises a log converter for log converting the received parameter and an adder for adding the volume control signal to the log parameter.

5. A selector stage according to claim 1 wherein the parameter is dependent on the peak value of the received signal.

6. A selector stage according to claim 5 wherein the parameter is a peak level envelope signal.

7. A selector stage according to claim 1 further comprising an input to receive a threshold signal; a comparator for comparing an output of the adjuster with the threshold signal; and wherein the selector selects the gain dependent on the comparison.

8. A selector stage according to claim 7 wherein the threshold signal is input to a processor before being passed to the comparator.

9. A selector stage according to claim 2 wherein the processor comprises a log converter and/or a scaling means.

10. A selector stage according to claim 7 wherein, when the output of the comparator indicates a gain adjustment is required, the gain is selected using a variable gain function.

11. A selector stage of claim 7 wherein the gain is selected using a variable gain function:
(a) when the output of the adjuster is greater than the threshold signal and a negative signal polarity; or
(b) when the output of the adjuster is less than the threshold signal and a positive signal polarity is utilised.

12. The gain selector of claim 10 wherein the variable gain function, or a factor of the variable gain, is:
K=2^{lgK} where
lgK=lgGs+m(lgGV+lgTA)
where K is the gain, lgGs is the volume control signal, lgGV is the output of the adjuster, lgTA is the threshold signal and m is a value indicative of a predetermined operational characteristic curve.

13. A signal processing circuit for amplifying a digital audio signal, comprising:
parameter determining processor for determining a parameter of said signal;
a gain selector according to claim 1; and
amplifier for amplifying said signal according to said gain.

14. A circuit according to claim 13 wherein the parameter determining processor is a peak detector.

15. A circuit according to claim 14 wherein the peak detector output is dependent on the peak levels in the signal waveform and a time dependent decay characteristic, wherein the decay characteristic is further dependent on the frequency of said signal.

16. A circuit according to claim 15 wherein the peak detector comprises a disabler for disabling the decay characteristic until the signal changes polarity.

17. A circuit according to claim 13 further comprising a delay for delaying said signal prior to said amplification in order to first determine said gain characteristic.

18. A peak detector comprising:
an input for receiving a signal;
peak level processor for determining peak levels in the signal; and
an output for outputting a signal dependent on said peak levels and a time dependent decay characteristic, wherein the decay characteristic is further dependent on the frequency of said received signal.

19. A detector according to claim 13 wherein the output comprises a disabler for disabling the decay characteristic until the signal changes polarity.

20. A signal level detector comprising:
an input to receive an input audio signal;
amplitude processor operable in a decay mode, being when the input audio signal is smaller than a previous output signal, whereby in the decay mode, the processor is configured to generate a signal for decreasing the amplitude of a signal to be output; and
logic device for controlling the operation of the amplitude processor in the decay mode such that the processor only generates a signal in the decay mode upon receipt of a trigger from the logic device, whereby the trigger is related to the frequency of the input audio signal.

21. A signal level detector comprising:
an input to receive an input audio signal;
amplitude processor configured to generate a signal for scaling the amplitude of a signal to be output; and
logic device for controlling the operation of the amplitude processor such that the processor only generates the signal for scaling upon receipt of a trigger from the logic device, whereby the trigger is related to the frequency of the input audio signal.

22. The signal level detector of claim 20 further comprising a comparator for determining when a change of sign occurs, wherein the comparator is associated with the logic device, and the logic device sends a trigger to the amplitude processor when a change of sign of the input signal occurs.

23. The signal level detector of claim 20 wherein the logic device comprises an input for receiving a timeout signal, and the logic device sends a trigger to the processor when a timeout signal is received.

24. The signal level detector of claim 23 further comprising a timeout counter which is configured to generate the timeout signal after a time period passes, corresponding to the lowest frequency of the input signal, without a change of sign occurring.

25. A method of determining a signal level of an audio signal comprising:
receiving an input audio signal;
comparing the input audio signal with a previous output signal to obtain a difference signal;
generating a scaled signal by scaling the difference signal using an attack coefficient or a decay coefficient, depending upon the comparison;
combining the scaled signal with the previous output signal to obtain a signal, indicative of the signal level of the input audio signal, characterised in that the method comprises:
controlling the generation of the scaled signal when scaled by the decay parameter, using a trigger related to the frequency of the input audio signal.

26. The method of claim 25 wherein only the generation of the indicative signal scaled signal by a decay parameter is controlled.

27. The method of claim 25, wherein the trigger is generated when a change of sign of the input signal occurs or a timeout occurs.

28. An integrated circuit comprising a signal level detector according to claim 20.

29. An integrated circuit comprising a gain selector stage according to claim 1.

30. Audio equipment comprising an integrator circuit according to claim 28.

31. Audio equipment comprising an integrator circuit according to claim 29.

32. Processor control code to, when running, implement the signal processing circuit of claim 13.

33. A carrier carrying the processor control code of claim 31.

34. The signal level detector of claim 21, further comprising a comparator for determining when a change of sign occurs, wherein the comparator is associated with the logic device, and the logic device sends a trigger to the amplitude processor when a change of sign of the input signal occurs.

35. The signal level detector of claim 21 wherein the logic device comprises an input for receiving a timeout signal, and the logic device sends a trigger to the processor when a timeout signal is received.

36. The signal level detector of claim 35, further comprising a timeout counter which is configured to generate the timeout signal after a period of time passes, corresponding to the lowest frequency of the input signal, without a change of sign occurring.
